(19) United States
(12) Patent Application Publication
(10) Pub. No.: US 2026/0143068 A1
(43) Pub. Date: May 21, 2026

(54) INFORMATION PROCESSING APPARATUS, CONTROL METHOD OF INFORMATION PROCESSING APPARATUS, AND STORAGE MEDIUM

(71) Applicant: CANON KABUSHIKI KAISHA, Tokyo (JP)

(72) Inventors: TAKASHI OCHIAI, Tokyo (JP); ATSUSHI USHIRODA, Kanagawa (JP)

(21) Appl. No.: 19/386,837

(22) Filed: Nov. 12, 2025

(30) Foreign Application Priority Data
Nov. 18, 2024 (JP) 2024-200824

(51) Int. Cl. H04N 1/00; G06F 3/04815; H04N 1/387

(52) U.S. Cl. CPC H04N 1/00045; G06F 3/04815; H04N 1/387

(57) ABSTRACT

Provided is implementation of inspection of a printed material, which eventually becomes a three-dimensional deliverable, taking into consideration a state of being formed into a three-dimensional. An information processing apparatus configured to inspect a printed material specifies a region pair formed of two regions, which are regions as an inspection target in a read image obtained by optically reading the printed material and which to be put in contact with each other in a case where the printed material is changed into the three-dimensional form. Then, the specified region pair is displayed on a display unit in an identifiable manner.

### BACKGROUND

### Field

The present disclosure relates to a technique of inspecting a printed material.

### Description of the Related Art

Conventionally, an inspection apparatus has been known, which automatically inspects a quality of a printed material. The above-described inspection apparatus inspects whether the printed material is a non-defective product or a defective product by comparing an image as a reference in a case of inspecting the printed material (referred to as a “reference image” or a “correct image”) and a read image obtained by reading the printed material (referred to as an “inspection image”). Japanese Patent Application Laid-Open No. 2017-228165 discloses a technique to perform inspection by printing a pattern (a trim mark) for positional misalignment inspection in a peripheral position of a pictorial pattern arranged on the obverse side and the reverse side of a sheet and correcting the positional misalignment between the obverse side and the reverse side.

Incidentally, a method of producing a three-dimensional deliverable has been known, which is performed by printing a developed view of a product package, cutting out an unnecessary portion from the obtained printed material, and assembling the printed material into the three-dimensional deliverable. The above-described inspection of the printed material for the product package is performed more efficiently by being performed before performing a step after printing such as cutting out and assembling; for this reason, in most cases, the inspection image obtained by reading the printed material in a plane state is used. In this case, a print defect in portions that are put in contact with each other in the form of the three-dimensional deliverable may be inconspicuous at the time of the printed material but become conspicuous once the printed material is formed into the three-dimensional deliverable. However, in the conventional inspection technique including Japanese Patent Application Laid-Open No. 2017-228165 described above, it has not been able to respond to a request to inspect for, at the time of the printed material, the print defect that may occur in the form of the three-dimensional deliverable.

### SUMMARY

Embodiments of the present disclosure implement inspection of a printed material, which eventually becomes a three-dimensional deliverable, taking into consideration a state of being formed into a three-dimensional form.

Embodiments of the present disclosure provide an information processing apparatus configured to inspect a printed material according to the present disclosure, having: one or more memories storing instructions; and one or more processors executing the instructions to: obtain a read image obtained by optically reading the printed material; specify a region pair formed of two regions, which are regions as an inspection target in the read image and which to be put in contact with each other in a case where the printed material is changed into a three-dimensional form; and display the specified region pair on a display unit in an identifiable manner.

Features of the present disclosure will become apparent from the following description of embodiments with reference to the attached drawings. The following description of embodiments are described by way of example.

### BRIEF DESCRIPTION OF THE DRAWINGS

FIG. 1 is a block diagram showing an overall configuration of a print inspection system;

FIG. 2 is a block diagram showing an overall configuration of the print inspection system to perform inspection processing via a cloud server;

FIG. 3 is a functional block diagram showing a software configuration of an information processing apparatus;

FIG. 4 is a flowchart showing a rough flow of the inspection processing;

FIG. 5A is a diagram showing an example of a GUI related to the inspection processing;

FIG. 5B is a diagram showing an example of the GUI related to the inspection processing;

FIG. 5C is a diagram showing an example of the GUI related to the inspection processing;

FIG. 6 is a flowchart showing details of region pair specification processing;

FIG. 7 is a diagram showing an example of the GUI related to the inspection processing;

FIG. 8 is a flowchart showing details of the inspection processing;

FIG. 9A is a diagram describing absolute positional misalignment, and FIG. 9B is a diagram describing relative positional misalignment;

FIG. 10A and FIG. 10B are diagrams describing a variation of positional misalignment;

FIG. 11A and FIG. 11B are diagrams describing a variation of positional misalignment;

FIG. 12 is a flowchart showing details of covered region specification processing;

FIG. 13 is a diagram showing an example of a result of performing the covered region specification processing; and

FIG. 14A is a diagram showing an example of a printed material to which an inspection mark is added, and FIG. 14B and FIG. 14C are enlarged views of the inspection mark.

### DESCRIPTION OF THE EMBODIMENTS

Hereinafter, with reference to the attached drawings, the present disclosure is explained in detail in accordance with embodiments. Configurations shown in the following embodiments are merely exemplary and the present disclosure is not limited to the configurations shown schematically.

### First Embodiment

In the present embodiment, an aspect is described, which allows for proper inspection of a printed material that eventually becomes a three-dimensional deliverable, by displaying regions that are distant from each other in a plane state of the printed material but are put in contact with each other in the three-dimensional form (hereinafter, referred to as a “region pair”) in a state recognizable by a user.

### Confirmation of Problem

Inspection of the printed material of a box-shaped product package, such as a caramel shape and a pillow shape created by using one or more printed materials, is performed more efficiently by being performed before performing a work such as cutting out and assembling. In a case of performing the inspection by reading the printed material in a plane state, a print defect in portions that are put in contact with each other in the form of the three-dimensional deliverable may be inconspicuous at the time of the printed material but become conspicuous once the printed material is formed into the three-dimensional deliverable. The print defect in this case includes, specifically, misalignment of a pictorial pattern and a shape that are completed after assembling, a difference in color and gloss between adjacent surfaces of the three-dimensional deliverable, and so on. It is considerably important for the product package as a face of a commercial product to execute proper inspection in the plane state in terms of eliminating restrictions in design, which are due to the difficulty in sufficient inspection in the plane state, and securing a degree of freedom of the design. Therefore, in the following embodiments, processing to implement inspection of the printed material, which eventually becomes the three-dimensional deliverable, taking into consideration a state of being formed into the three-dimensional form is performed.

### Configuration of Print Inspection System

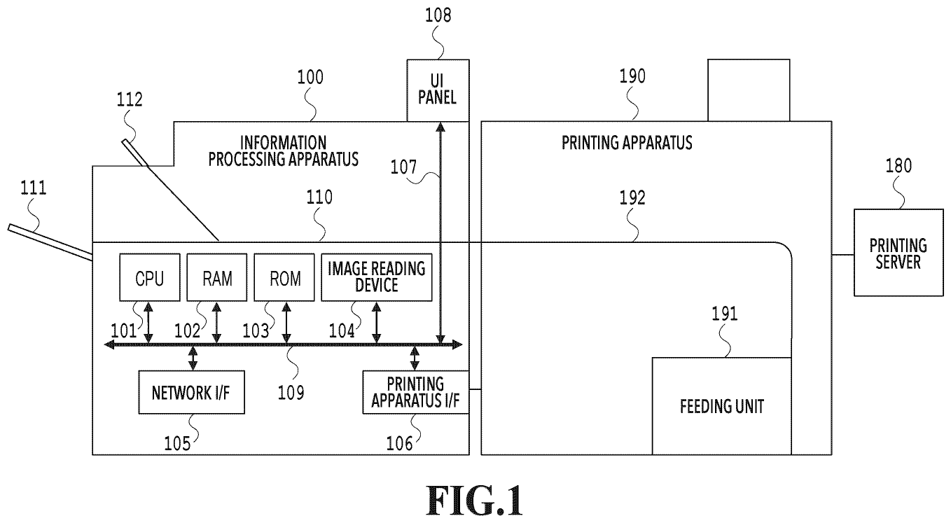

FIG. 1 is a diagram showing an overall configuration of a print inspection system to output and inspect the printed material, which includes an information processing apparatus according to the present embodiment. The print inspection system shown in FIG. 1 includes an information processing apparatus 100 that performs post-processing such as the inspection and stapling of the printed material, a printing server 180 that generates and outputs a print job, and a printing apparatus 190 that performs print processing based on the print job.

Based on the print job inputted from the printing server 180, the printing apparatus 190 forms an image on a recording medium for printing (hereinafter, referred to as a “sheet”) such as paper and a plastic sheet. The printing apparatus 190 includes a feeding unit 191, and a user sets the sheet to the feeding unit 191 in advance. Once the print job is inputted, the printing apparatus 190 forms the image on one side or two sides of the sheet while conveying the sheet set to the feeding unit 191 along a conveyance path 192 and sends out the sheet to the information processing apparatus 100. A printing method of the printing apparatus 190 is an electrophotographic method. Another printing method such as an ink jet method may be applied, and the printing method is not particularly limited.

The information processing apparatus 100 inspects for a defect on the sheet on which the print processing has been performed (hereinafter, referred to as a “printed material”). The information processing apparatus 100 includes a CPU 101, a RAM 102, and a ROM 103, and a function of each unit in the apparatus is implemented with the CPU 101 executing a program stored in the RAM 102 or the ROM 103. The information processing apparatus 100 optically reads the printed material conveyed through the conveyance path 192 in the printing apparatus 190 by an image reading device 104 such as a scanner and a camera and obtains a read image for the inspection (hereinafter, referred to as an “inspection image”). Then, the printed material is inspected in the plane state by comparing the obtained inspection image and an image as an inspection reference (hereinafter, referred to as a “reference image”). Additionally, the information processing apparatus 100 includes various interfaces such as a network I/F 105, a printing apparatus I/F 106, and a general-purpose I/F 107 and a user interface (UI) panel 108 that allows the user to input an operation or confirm an inspection result, for example. In addition, modules in the information processing apparatus 100 are connected to each other via a main bus 109.

The information processing apparatus 100 includes a conveyance path 110 connected with the conveyance path 192 in the printing apparatus 190, and the image reading device 104 reads one side or two sides of the printed material sent from the printing apparatus 190 by scanning the printed material on the conveyance path 110 to obtain inspection image data. The printing apparatus I/F 106 is connected with the printing apparatus 190, and the information processing apparatus 100 can communicate with the printing apparatus 190 through the printing apparatus I/F 106. For example, it is possible to synchronize the printing apparatus 190 and the information processing apparatus 100 via the printing apparatus I/F 106 and notify of a working situation to each other. The UI panel 108 is a display device such as a liquid crystal display and functions as a user interface that provides the user with a current situation, setting information, or the like of the information processing apparatus 100. Additionally, the UI panel 108 may include an input device such as a touch panel or a button, and the UI panel 108 can receive an instruction from the user.

While the printed material outputted from the printing apparatus 190 is moved on the conveyance path 110, the information processing apparatus 100 inspects whether there is a print defect by using the inspection image and the corresponding reference image. If it is determined that the printed material passes the inspection as a result of the inspection, the printed material is conveyed to an output tray 111. If it is determined that the printed material fails the inspection as a result of the inspection processing, the printed material is conveyed to an output tray 112. According to the above-described discharge operation, only the printed material determined to have no defect is outputted on the output tray 111. Note that, the information processing apparatus 100 may be implemented by multiple information processing apparatuses.

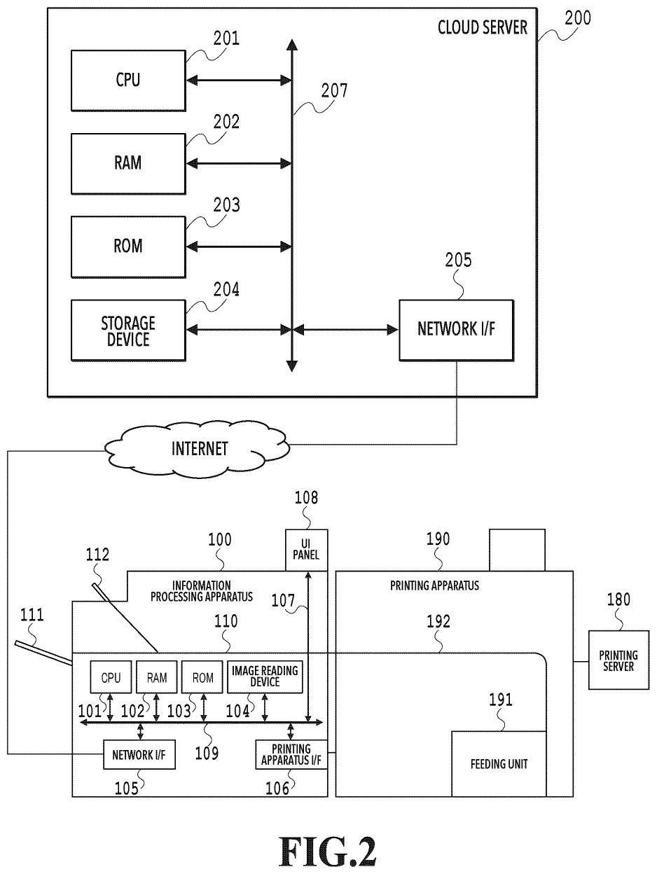

FIG. 2 is a diagram showing a system configuration example in a case where a cloud server is added to the system configuration shown in FIG. 1 to perform the inspection via the cloud server. A cloud server 200 is a server apparatus that provides a cloud service on the Internet. The cloud server 200 receives the inspection image data obtained by the image reading device 104 of the information processing apparatus 100, inspects the printed material, and transmits the inspection result to the information processing apparatus 100 as needed. The cloud server 200 includes a CPU 201, a RAM 202, a ROM 203, a storage device 204, and a network I/F 205, and the constituents are connected to each other through a system bus 207. Note that, the cloud server 200 may be formed of a single server apparatus or may be formed of multiple server apparatuses. Additionally, functions of multiple server apparatuses may be implemented by a single server apparatus by virtualization software. Moreover, the cloud server 200 may be connected with not only the information processing apparatus 100 but also with the printing apparatus 190 to manage the print job and the inspection result.

### Function of Information Processing Apparatus

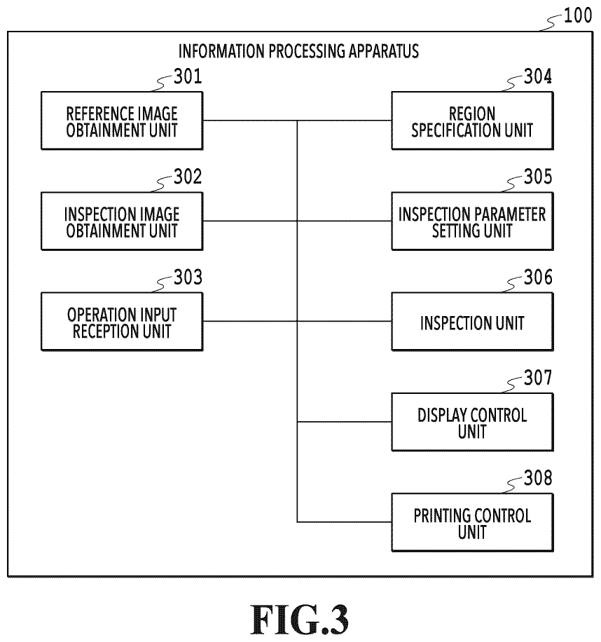

Subsequently, a software configuration (a logical configuration) of the information processing apparatus 100 is described. FIG. 3 is a functional block diagram showing a software configuration of the information processing apparatus 100. The information processing apparatus 100 includes a reference image obtainment unit 301, an inspection image obtainment unit 302, an operation input reception unit 303, a region specification unit 304, an inspection parameter setting unit 305, an inspection unit 306, a display control unit 307, and a printing control unit 308.

The reference image obtainment unit 301 obtains the reference image to be compared with the inspection image. The reference image is obtained by scanning the printed material that is visually confirmed by the user that there is no print defect. Alternatively, a printed image obtained by performing RIP processing on PDL data and the like included in the print job may be used as the reference image.

The inspection image obtainment unit 302 obtains the inspection image of the printed material as an inspection target. The inspection image is obtained by reading the printed material outputted from the printing apparatus 190 by the image reading device 104.

The operation input reception unit 303 receives an operation input from the user that is, for example, designation of the region pair of the regions put in contact with each other in the three-dimensional form on the inspection image and an input of an inspection parameter.

The region specification unit 304 specifies a pair of regions (the region pair) that are put in contact with each other in a case of forming the three-dimensional deliverable by assembling the plane printed material. The specification may be performed automatically or may be performed manually, as described later.

The inspection parameter setting unit 305 sets the inspection parameter based on an operation input and the like by the user. The inspection parameter is a threshold for determining a passing status that corresponds to an inspection item, and in the present embodiment, the inspection parameter for the above-described region pair and the inspection parameter for a region other than the region pair are set separately. The inspection item includes misalignment of a pictorial pattern and a shape that occurs after assembling and the like, a difference in color and gloss between adjacent surfaces of the three-dimensional deliverable, and so on. Based on the set inspection parameter, the inspection unit 306 inspects whether the inspection image includes the print defect.

The display control unit 307 performs display control of a graphical user interface (GUI) using the UI panel 108. For example, the display control unit 307 displays each region pair on the inspection image in a state that allows the user to identify it and displays the inspection result.

The printing control unit 308 controls the printing apparatus 190. For example, according to the contents of the printed image, the printing control unit 308 adds a position adjustment mark and the inspection mark corresponding to the above-described region pair to the printed image and causes the printing apparatus 190 to execute the print processing.

### Operation Flow of Information Processing Apparatus

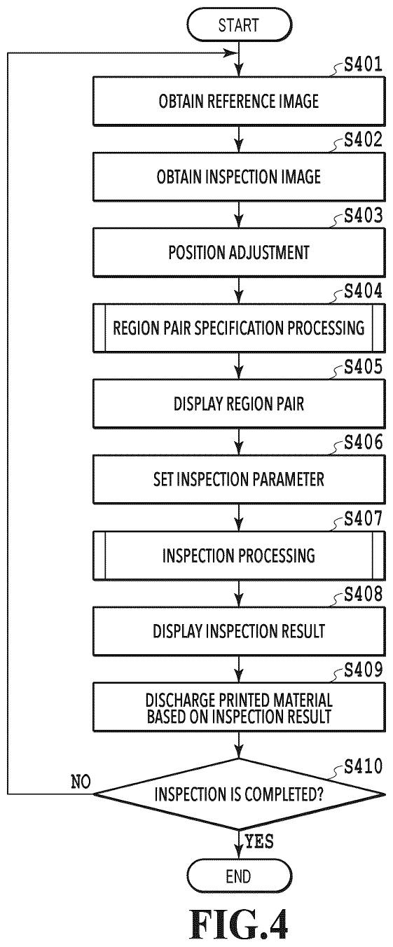

FIG. 4 is a flowchart showing a rough flow of the inspection processing by the information processing apparatus 100. A series of processing shown in the flowchart in FIG. 4 is implemented with the CPU 101 reading a control program stored in the ROM 103 or another storage device and deploying to the RAM 102 to execute. Additionally, the data used in the series of processing is stored in the ROM 103 or the RAM 102 or a storage device additionally prepared and is read to be used for the processing as needed. In the following, description is provided according to the flowchart in FIG. 4. Note that, a symbol “S” means a step.

In S401, the reference image obtainment unit 301 obtains the reference image corresponding to the printed material according to an inspection target page outputted from the printing apparatus 190. Next, in S402, the inspection image obtainment unit 302 obtains the inspection image of the printed material according to the inspection target page.

In S403, position adjustment between the reference image obtained in S401 and the inspection image obtained in S402 is performed. For example, four corners of the printed material, the position adjustment mark additionally added, or the like is utilized to perform position adjustment so as to associate each position in the reference image with each position in the inspection image.

In S404, the region specification unit 304 performs processing of specifying the region pair of the regions that are distant from each other on the printed material but are put in contact with each other in a case where the printed material is formed into the three-dimensional deliverable. The specification of the region pair is, for example, automatic specification performed by obtaining three-dimensional CAD data of the printed material according to the inspection image and analyzing a 3D image expressing a shape of the printed material in a case of being changed into the three-dimensional form by an artificial intelligence (AI) technique. Alternatively, the specification may be performed with the user directly designating the region pair via the GUI while confirming the inspection image. Alternatively, instead of the specification of the region pair, a table and the like prepared in advance by the user may be obtained and referred to, which associate the region in the printed material in the plane state and a side in a case of being formed into the three-dimensional deliverable. Details of the region pair specification processing according to the present embodiment are described later.

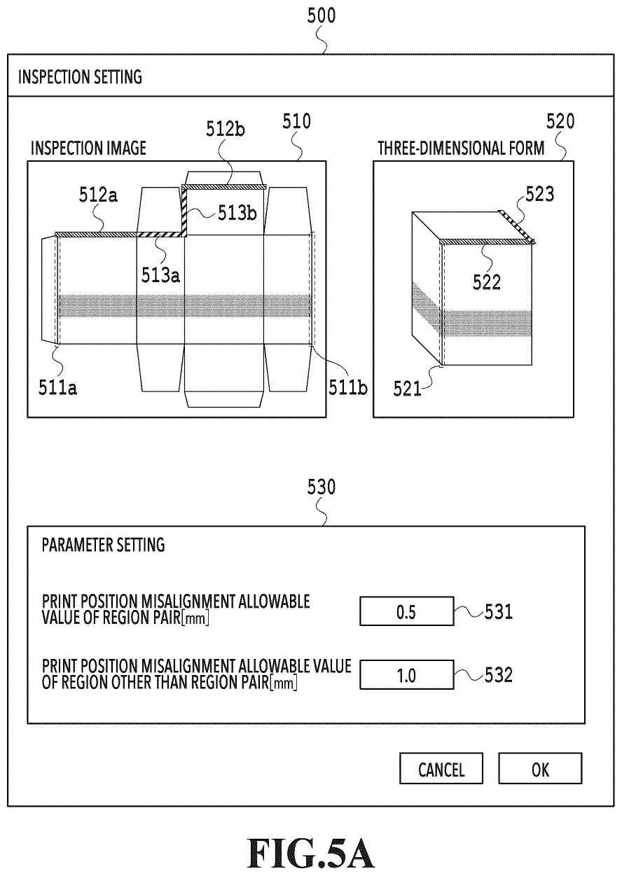

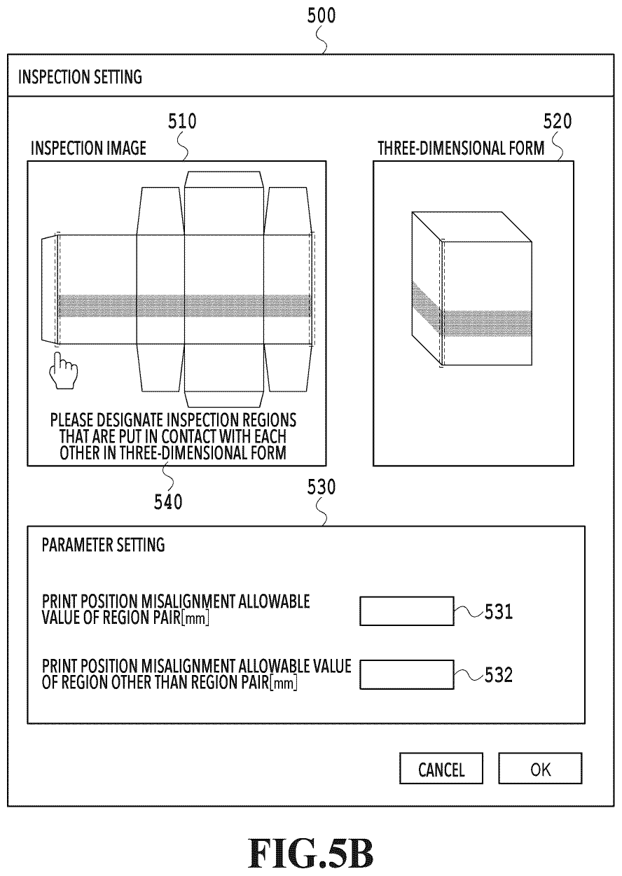

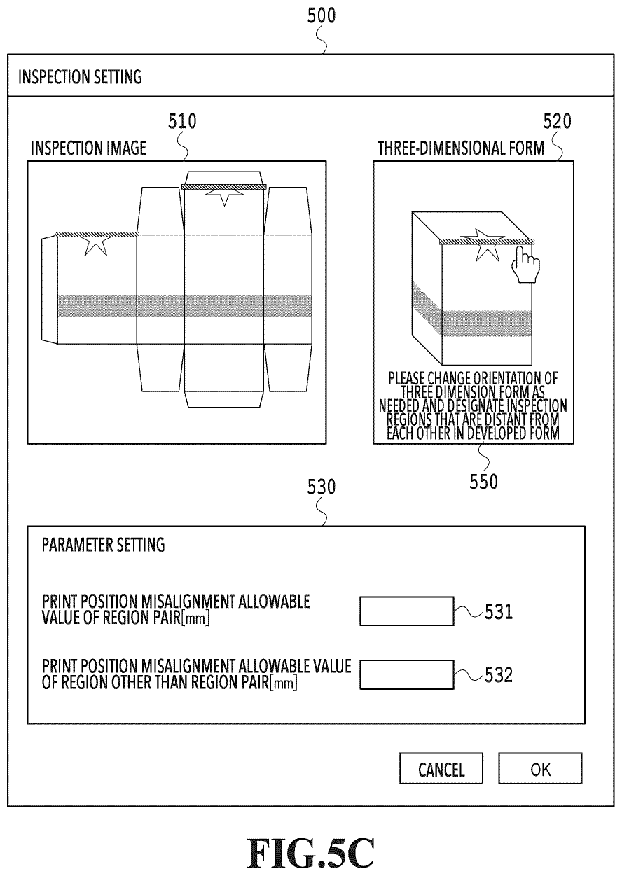

In S405, the display control unit 307 displays the region pair specified in S404 on the GUI of the UI panel 108 in a state that allows the user to identify it. FIG. 5A is an example of the GUI related to the inspection processing according to the present embodiment. A UI screen 500 shown in FIG. 5A includes a first pane 510 to display the inspection image, a second pane 520 to display the 3D image corresponding to the inspection image, and a third pane to set the inspection parameter. Currently, in the first pane 510, the inspection image obtained by scanning the printed material of the box-shaped product package is displayed. In addition, different patterns are superimposed on three region pairs 511 to 513 specified in S404, respectively, in the inspection image, and each region pair is highlight-displayed in an identifiable manner. In this case, the region pair 511 is formed of a region 511a and a region 511b, the region pair 512 is formed of a region 512a and a region 512b, and the region pair 513 is formed of a region 513a and a region 513b. Although there are also other region pairs exist, the three region pairs are shown for the sake of description. All the region pairs specified in S404 may be displayed, or only a part of the region pairs that is, for example, a conspicuous portion of the product package may be displayed. In the second pane 520, the 3D image corresponding to the inspection image is displayed, and additionally, three sides 521 to 523 corresponding to the region pairs 511 to 513 highlight-displayed in the first pane 510 are highlight-displayed similarly. Note that, highlight-displaying of the region pair may be performed in only either one of the inspection image in the first pane and the 3D image in the second pane. Additionally, although a different pattern is applied to each region pair in the above-described example, for example, a color may be different with the same pattern, or a unique character string such as “pair 1” and “pair 2” may be applied, for example. Moreover, instead of the static expression as described above, for example, highlight-displaying may be performed by dynamic expression such as different blinking timings or sequential switching one by one. Furthermore, transparency processing may be performed on the inspection image or the 3D image to perform displaying to allow only the region pair to be visually confirmed.

In S406, based on an operation input of the user received by the operation input reception unit 303, the inspection parameter setting unit 305 sets the inspection parameter. For example, in a case of the UI screen 500 shown in FIG. 5A described above, the user uses input boxes 531 and 532 in the third pane and sets the inspection parameter for the region pair and the inspection parameter for the region other than the region pair separately. In this case, the user may select the region pair to focus from the region pairs highlight-displayed in the first pane 510 and may set the desired inspection parameter for each region pair. Note that, the UI screen 500 is an example in a case of setting an allowable value in a case where the inspection item is “positional misalignment,” and it is possible to set a different allowable value (an inspection threshold) for each inspection item, for example. In this case, for example, the allowable value for the region pair may be automatically set so as to be smaller than the allowable value for the region other than the region pair (that is, so as to make an inspection level strict). Alternatively, multiple allowable values may be prepared in advance so as to be automatically set according to a feature amount (complexity) of the pictorial pattern. Additionally, a different inspection parameter may be set for each region pair.

In S407, based on the inspection parameter set in S406, the inspection unit 306 compares the reference image obtained in S401 and the inspection image obtained in S402, and based on a difference between the two images, the inspection unit 306 inspects whether there is the print defect. Details of the inspection processing are described later.

In S408, the display control unit 307 displays a result of the inspection in S407 on the GUI. In the subsequent S409, whether the inspection of all the pages of the inputted print job is completed is determined. If there is a page not processed yet, the processing returns to S401, and the processing continues by targeting the next page. On the other hand, if the inspection of all the pages is completed, the present processing ends. The above is the rough flow of the inspection processing by the information processing apparatus 100.

### Details of Region Pair Specification Processing

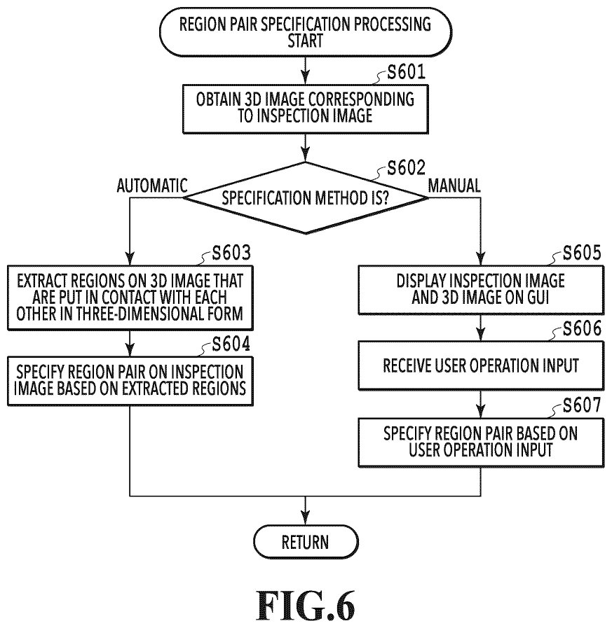

Subsequently, the region pair specification processing in S404 is described in detail. FIG. 6 is a flowchart showing details of the region pair specification processing. In the following, description is provided along a flow in FIG. 6. In the following description, a symbol [S] means a step.

In S601, the 3D image corresponding to the inspection image obtained in S402 is obtained. In this case, for example, the 3D image may be obtained by holding three-dimensional CAD data of all the pages, which is inputted with the print job into the information processing apparatus 100, in a not-shown storage device in advance, and reading the data of the inspection target page.

In S602, processing subsequently executed is allocated depending on how to specify the region pair. In a case of automatic specification, S603 is executed, and in a case of manual specification, S605 is executed.

In S603, for example, the 3D image obtained in S601 is inputted to a pre-trained learning model, and the regions that are put in contact with each other in a case where the printed material according to the inspection image is changed into the three-dimensional form are extracted. In the subsequent S604, based on the regions extracted in S603 that are put in contact with each other, each region pair on the inspection image obtained in S402 is specified. Note that, the method of automatically specifying the region pair is not limited to the above-described example and, for example, the region pair in the inspection image may be specified by estimating a state of the three-dimensional form from the inspection image by utilizing an AI technique and the like.

In S605, the inspection image obtained in S402 and the 3D image obtained in S601 are displayed in the first pane and the second pane on the GUI, respectively. FIGS. 5B and 5C are examples of the GUI in a case where the user manually designates the region pair, while FIG. 5B is an example of the GUI in a case of designating the region pair on the inspection image, and FIG. 5C is an example of the GUI in a case of designating the region pair on the 3D image. In a case of a GUI 500 shown in FIG. 5B, a message prompting designation of the region pair is displayed in the first pane 510, and the user can designate a pair of regions forming the region pair by using an input device such as a mouse. In a case of the GUI 500 shown in FIG. 5C, a message prompting designation of the region pair is displayed in the second pane 520, and the user can designate a pair of regions forming the region pair by using an input device such as a mouse. In this case, once the region pair is designated in either one of the panes, contents indicating the designated region pair may be reflected in the other pane.

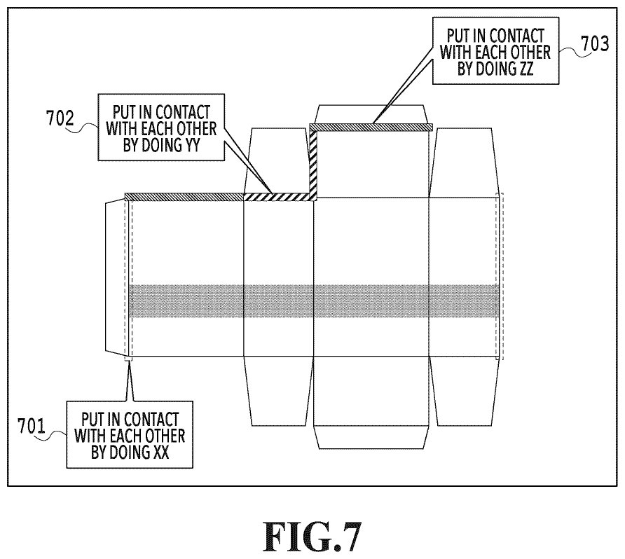

In S606, an operation input from the user to designate the pair of regions forming the region pair on the inspection image or on the 3D image (the two regions that are distant from each other in the plane state but are put in contact with each other in a case of being formed into the three-dimensional form) is received. In the subsequent S607, the pair of regions according to the user operation input received in S606 is specified as the region pair. The user performs each step in S606 and S607 for each desired region pair. Thus, once the automatic or manual specification of the region pair is completed, the processing returns to the main flow in FIG. 4, and the specified one or more region pairs are highlight-displayed in S405. In this case, as described above, individual region pair is displayed in an identifiable manner; however, for example, as shown in FIG. 7, a description text as supplemental information indicating how the regions of each region pair are put in contact with each other (for example, rotate 90 degrees, flip horizontal, flip vertical, and the like) may be displayed on the GUI. Thus, the user can understand more easily a difference in the positional relationship between the time of the inspection and the time of the three-dimensional form. Above is the details of the region pair specification processing.

### Details of Inspection Processing

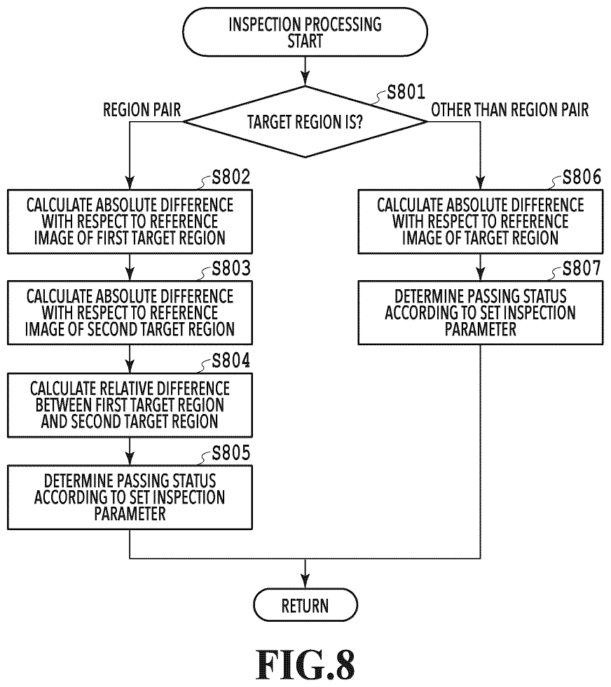

Subsequently, the inspection processing in S407 is described in detail. FIG. 8 is a flowchart showing details of the inspection processing. The inspection processing is executed by a predetermined unit of region in the inspection image depending on whether there is the region pair, the inspection item, and the like. In the following, description is provided along a flow in FIG. 8 using as an example the inspection for the positional misalignment in a case where the two regions that are distant from each other but have pictorial patterns that are connected in a case of being formed into the three-dimensional form are set as the region pair. In the following description, a symbol [S] means a step.

In S801, the processing subsequently executed is allocated depending on whether the target region of the inspection processing in the inspection image obtained in S402 is the regions of the region pair. If the target region is the regions of the region pair, S802 is executed subsequently, and if the target region is the region other than the region pair, S806 is executed subsequently.

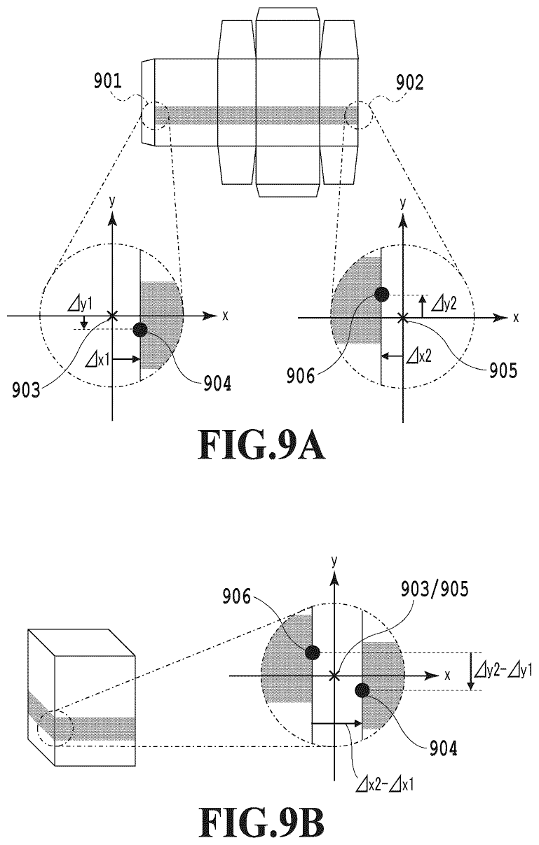

In S802, an absolute difference value with respect to the reference image is calculated for one of the two regions forming the region pair focused as the target region (hereinafter, referred to as a “first target region”). In the subsequent S803, an absolute difference value with respect to the reference image is calculated for the other region of the two regions forming the region pair focused as the target region (hereinafter, referred to as a “second target region”). FIG. 9A is a diagram describing absolute positional misalignment with respect to the reference image between the first target region and the second target region of a certain region pair on the inspection image. In FIG. 9A, x mark 903 indicates an ideal position of a pixel in a first target region 901 in the inspection image, and a black circle mark 904 indicates an actual pixel position. Additionally, a x mark 905 indicates an ideal position of a pixel in a second target region 902 in the inspection image, and a black circle mark 906 indicates an actual pixel position. Currently, the first target region 901 is misaligned by Δx1 in an x direction and Δy1 in a y direction, respectively, and the second target region 902 is misaligned by Δx2 in the x direction and Δy2 in the y direction, respectively. In a case where the inspection item is a print position misalignment amount, the absolute difference value is calculated as described above.

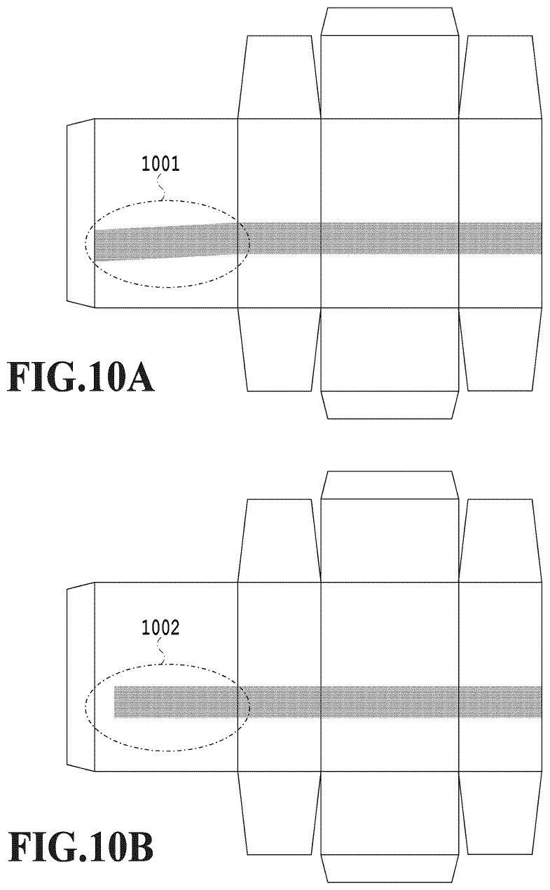

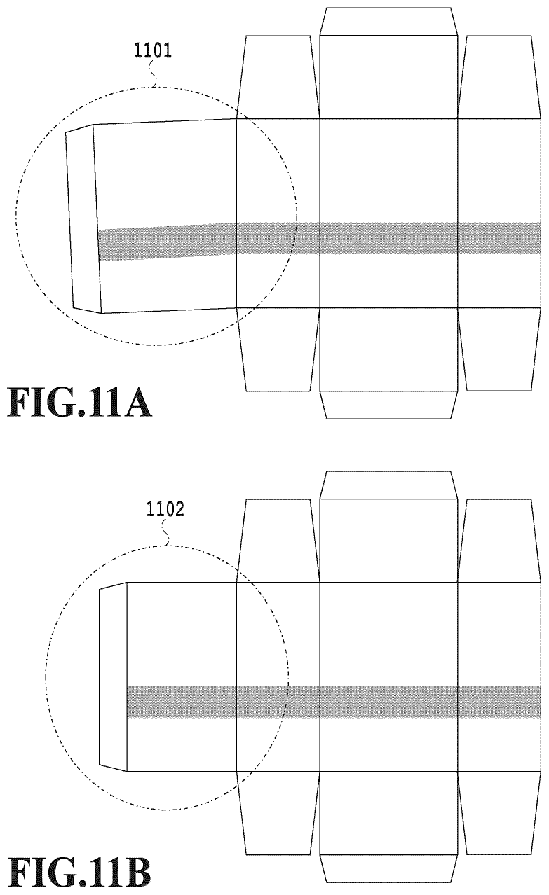

In S804, a relative difference value between the absolute difference value with respect to the reference image of the first target region calculated in S802 and the absolute difference value with respect to the reference image of the second target region calculated in S803 is calculated. FIG. 9B is a diagram describing a situation in which a positional misalignment amount as the relative difference value is obtained in the specific example shown in FIG. 9A described above. As shown in FIG. 9B, while the x mark 903 and the x mark 905 indicating the ideal pixel position are consistent with each other, the black circle mark 904 and the black circle mark 906 indicating the actual pixel position are misaligned by “Δx2−Δx1” in the x direction and “Δy2−Δy1” in the y direction. As a result, in a case of being formed into the three-dimensional form, the pictorial pattern is misaligned vertically and horizontally by the above-described relative positional misalignment amount between the first target region and the second target region of the region pair. FIGS. 10 and 11 are diagrams describing variations of the positional misalignment that may be the inspection target. FIGS. 10A and 10B are specific examples in which the whole shape (edge) is printed correctly, but the pictorial pattern inside is printed incorrectly. FIG. 10A shows a case where a left end portion of a pictorial pattern 1001 is distorted in an oblique lower left direction, and FIG. 10B shows a case where a left end portion of a pictorial pattern 1002 is cut off. Additionally, FIGS. 11A and 11B are specific examples in which the shape is printed incorrectly, while FIG. 11A shows a case where a circular box portion 1101 is distorted in the oblique lower left direction, and FIG. 11B shows a case where a circular box portion 1102 is contracted in the horizontal direction. Note that, although it is not shown as a specific example, as a matter of course, there may be a case where both the shape and pictorial pattern are printed in the distorted manner. In any of the cases, the absolute positional misalignment amount with respect to the reference image is obtained for the first target region and the second target region of the region pair on the inspection image, and based on a result thereof, the relative positional misalignment amount is obtained. Therefore, it is possible to detect the positional misalignment that is not allowed in a case of the three-dimensional form.

In S805, the passing status is determined according to the inspection parameter set for the region pair in S406. Thus, for example, in the two regions that are distant from each other on the inspection image and form a certain pictorial pattern of the product package, it is possible to detect the positional misalignment that is within an acceptable range in each individual region but that is out of the acceptable range in a case of being formed into the three-dimensional form. Note that, in package printing, label printing, and the like, in a case where an assembling error in the three-dimensional form is known in advance, a relative difference may be calculated by providing the allowable value with a margin by the amount of the assembling error, for example.

In S806, the absolute difference value with respect to the reference image is calculated for the region other than the region pair that is focused as the target region. In the subsequent S807, the passing status is determined according to the inspection parameter set for the region in S406.

The above is the details of the inspection processing. Although a case of inspecting the misalignment of the pictorial pattern and the shape in the region pair is described, it is also possible to similarly inspect for a difference in color (color shift) in the region pair, for example. In a case of inspecting for the color shift, the region pair having the same color in both regions in a case of being formed into the three-dimensional form is specified, an allowable value of a color difference ΔE in the specified region pair is set, and the inspection for the color shift is performed based on the set allowable value. In this case, the allowable value of the color shift may be automatically set according to a feature amount of a color (shade, area, change in color). For example, in a case where the color of both regions of the specified region pair is, for example, a contrasty color such as black, or in a case where the specified region pair is a conspicuous portion of the product package and a single color is used widely, the change in the color is noticeable; for this reason, the allowable value may be set strictly. Additionally, in addition to the color shift, it is possible to similarly perform inspection for various image quality items such as gloss, graininess, and sharpness.

### Modification Example

In the above-described embodiment, the region pair is displayed on the GUI in an identifiable manner before setting the inspection parameter; however, for example, the region pair may be printed on an inspection report indicating a result of the inspection. Alternatively, the region pair may be printed additionally on a portion in the printed material that is to be unnecessary in the form of the three-dimensional deliverable (so-called waste obtained in stripping processing).

As above, according to the present embodiment, it is possible to specify the region pair of the regions that are distant from each other on the printed material but are put in contact with each other in a case of being changed into the three-dimensional deliverable, and it is possible to perform the inspection in the plane state to determine whether there is the print defect in the region pair.

### Second Embodiment

For example, in a case of package printing, there is a region in the printed material that overlaps with another region and becomes visually unconfirmable in a case of being formed into the three-dimensional form (an overlapping region). Additionally, for example, in a case of label printing and sticker printing, there is a region in the printed material that becomes visually unconfirmable or that becomes difficult to visually confirm in a case of wrapping around or adhering to the product, depending on the shape of the product. It can be said that the necessity of the inspection is low for the above-described region that is unconfirmable or inconspicuous on the eventual three-dimensional deliverable (hereinafter, referred to as a “covered region”). Therefore, an aspect in which the inspection level for the covered region in the printed material is set low, or the covered region is excluded from the inspection target is described as an embodiment 2. Note that, since the basic configuration and the like of the print inspection system are common to that of the embodiment 1, in the following, an operation flow of the information processing apparatus according to the present embodiment, which is a different point, is described.

### Operation Flow of Information Processing Apparatus

A difference between the inspection processing according to the present embodiment and the inspection processing according to the embodiment 1 appears in S404 and S405 in the series of processing shown in the flowchart in FIG. 4 described above. That is, in the present embodiment, in S404, “covered region specification processing” is executed instead of the “region pair specification processing,” and in S405, “displaying the covered region” is performed instead of “displaying the region pair.”

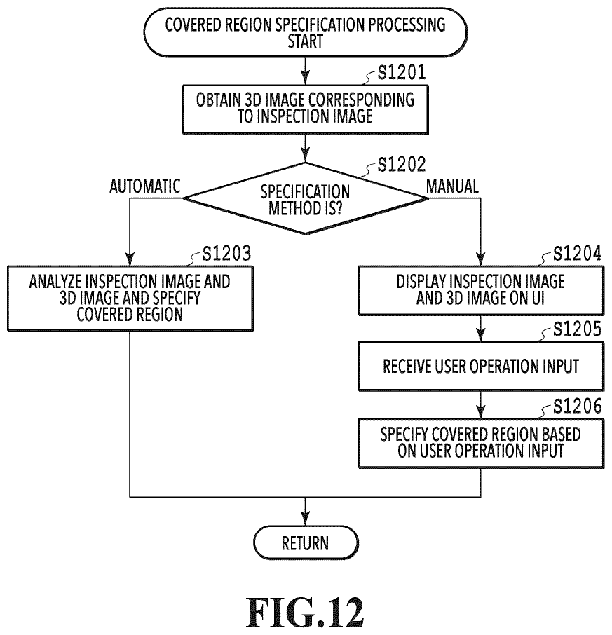

FIG. 12 is a flowchart showing details of the covered region specification processing according to the present embodiment. In the following, description is provided along a flow in FIG. 12. In the following description, a symbol [S] means a step.

In S1201, the 3D image corresponding to the inspection image obtained in S402 is obtained. In this case, for example, the 3D image may be obtained by holding three-dimensional CAD data of all the pages, which is inputted with the print job into the information processing apparatus 100, in a not-shown storage device in advance, and reading the data of the inspection target page.

In S1202, processing subsequently executed is allocated depending on how to specify the covered region. In a case of automatic specification, S1203 is executed, and in a case of manual specification, S1204 is executed.

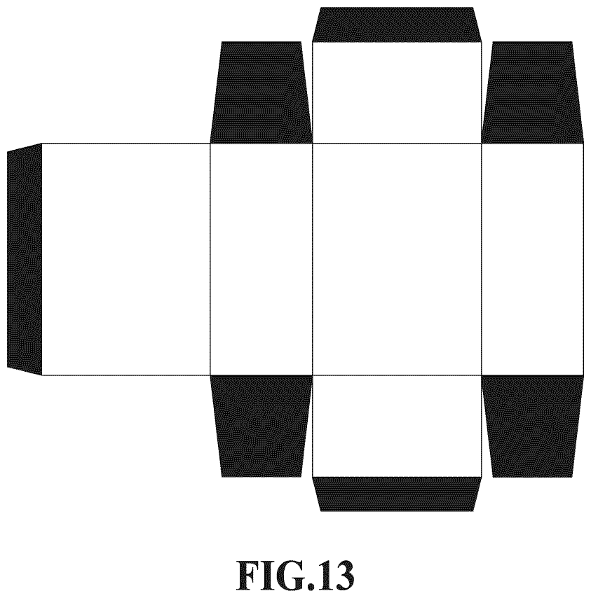

In S1203, for example, the inspection image obtained in S402 and the 3D image obtained in S1201 are inputted to a pre-trained learning model, and the covered region in the inspection image is specified. FIG. 13 shows a result of performing the covered region specification processing according to the present embodiment on the inspection image obtained by scanning the printed material of the box-shaped product package. In FIG. 13, a region colored in black indicates the specified covered region, and other regions in white indicate a region other than the covered region.

In S1204, the inspection image obtained in S402 and the 3D image obtained in S1201 are displayed on the GUI. The user operates an input device such as a mouse according to a message and the like prompting designation of the covered region displayed in the GUI and, for example, designates the covered region existing in the inspection image. Note that, since the covered region is a region that does not appear on the 3D image, the covered region may not be displayed on the GUI of the 3D image.

In S1205, an operation input from the user to designate the covered region on the inspection image is received. In the subsequent S1206, a region according to the user operation input received in S1205 is specified as the covered region. The user may designate all the covered regions on the inspection image or may designate only a part of the covered regions.

Thus, once the automatic or manual specification of the overlapping region is completed, the processing returns to the main flow, and the specified one or more covered regions are highlight-displayed in S405. The above is the details of the covered region specification processing.

Thereafter, in S406 of the main flow, based on the operation input of the user received by the operation input reception unit 303, the inspection parameter for the covered region and the inspection parameter for the region other than the covered region are set separately. In this case, as described above, the user sets the allowable value for the covered region so as to be greater than the allowable value for the region other than the covered region (so as to loosen the inspection level), or so as to exclude the covered region from the inspection target. In this case, the allowable value greater than that of the region other than the covered region may be inputted automatically for the covered region in a case where the allowable value for the region other than the covered region is inputted. Additionally, a relationship of the allowable values between the covered region and the region other than the covered region or whether to exclude the region other than the covered region from the inspection target may be determined depending on a type of the sheet.

As above, according to the present embodiment, in a case of inspecting the printed material, the inspection level for the region that is unconfirmable or the region that is inconspicuous at the time of the three-dimensional deliverable is set to be low, or the region is excluded from the inspection target. Thus, the inspection of the printed material is limited to a necessary range, and it is possible to suppress a reduction in the productivity of the print inspection system.

### Third Embodiment

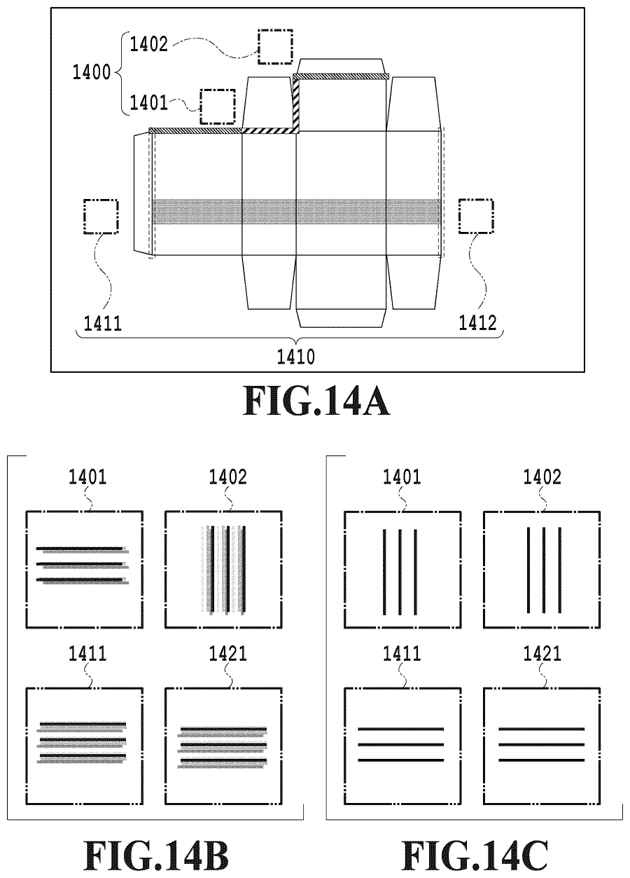

Next, an aspect in which a mark for the inspection corresponding to each region pair (hereinafter, referred to as an “inspection mark”) is printed on a margin and the like of the sheet to be utilized for the inspection is described as an embodiment 3. The inspection mark is also referred to as an inspection pattern. Note that, description of a portion common to the embodiment 1 is omitted, and in the following, a portion unique to the present embodiment is mainly described with reference to FIGS. 14A to 14C.

FIG. 14A is an example of the printed material to which the inspection mark is added, which is outputted by the printing apparatus 190 in the present embodiment. In the example in FIG. 14A, a first inspection mark formed of a pair of marks 1401 and 1402 and a second inspection mark formed of a pair of marks 1411 and 1412 are printed for two region pairs 1400/1410, respectively. FIGS. 14B and 14C are enlarged views of the first inspection mark and the second inspection mark in FIG. 14A, while FIG. 14B shows a case where the region pair fails the inspection, and FIG. 14C shows a case where the region pair passes the inspection.

In FIG. 14B, the marks 1401 and 1402 forming the first inspection mark have a stripe pattern in a direction in which color plate misalignment sensitively reacts, which is appropriate to evaluate the positional misalignment (the color plate misalignment) for each color in each of the two regions of the region pair 1400. The two regions of the region pair 1400 in a case of being formed into the three-dimensional form are put in contact with each other so as to be flipped 90 degrees from the plane state. Therefore, the mark 1401 has a stripe pattern appropriate for the evaluation in the horizontal direction, and the mark 1402 has a stripe pattern appropriate for the evaluation in the vertical direction. Both the marks 1401 and 1402 are a high frequency stripe pattern formed of straight lines corresponding to colors of printing color materials (for example, CMYK) and indicate a state that the straight lines of the colors are slightly misaligned from each other. In a case where there is completely no positional misalignment between the color plates, the pair of marks 1401 and 1402 are printed such that the straight lines corresponding to the colors are superimposed on the same position, and thus the stripe pattern is not obtained as shown in FIG. 14C.

Likewise, in FIG. 14B, the marks 1411 and 1412 forming the second inspection mark have a stripe pattern formed of straight lines in a direction that allows for easy detection of whether there is a level difference in the pictorial pattern at a boundary in the region pair 1410 in a case where a gray pictorial pattern 1420 extending in the horizontal direction is formed into the three-dimensional form. Both the marks 1411 and 1412 are high frequency stripe pattern formed of straight lines corresponding to colors of printing color materials (for example, CMYK) and indicate a state that the straight lines of the colors are slightly misaligned from each other. In a case where there is completely no positional misalignment between the color plates, the pair of marks 1411 and 1412 are printed such that the straight lines corresponding to the colors are superimposed on the same position, and thus the stripe pattern is not obtained as shown in FIG. 14C.

The inspection mark formed of a pair of marks as described above is arranged and printed on a position within a sheet that is, for example, discarded in a case of cutting and is a position close to each region pair by the printing control unit 308 depending on the contents of the printed image. In addition, in the inspection processing, a pixel value of the mark portion included in the inspection image is analyzed, for example, and whether the color plate misalignment exceeding the allowable value occurs is determined. Note that, an inspector may directly and visually check the inspection mark formed on the printed material to confirm whether the color plate misalignment occurs.

Note that, although the printed image to which the inspection mark is added is generated and printed, and the inspection is performed based on the inspection mark included in the inspection image in the above-described example, it is not limited thereto. For example, the inspection mark may be additionally printed on the printed material obtained by printing without adding the inspection mark, and the inspection may be performed based on the inspection mark included in the inspection image. Additionally, the inspection mark may be variable depending on the purpose of the inspection, and for example, for the purpose of inspecting the color shift, a color patch of at least one or more colors that are dominant in the two regions forming the region pair may be added as the inspection mark. Thus, it is possible to automatically analyze or visually confirm by the inspector the color shift between the regions of the region pair. Additionally, in addition to the color shift, for example, the present embodiment is similarly applicable to various image quality items such as gloss, sharpness, and graininess.

As above, according to the present embodiment, the inspection is performed by additionally printing the inspection mark depending on the purpose of the inspection in the position close to the region pair. Thus, it is possible to improve the inspection accuracy, and it is also possible to easily perform the visual inspection by the inspector.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

According to the present disclosure, it is possible to implement inspection of a printed material, which eventually becomes a three-dimensional deliverable, taking into consideration a state of being formed into a three-dimensional form.

This application claims the benefit of Japanese Patent Application No. 2024-200824, filed Nov. 18, 2024, which is hereby incorporated by reference herein in its entirety.

What is claimed is:

1. An information processing apparatus configured to inspect a printed material, the information processing apparatus comprising:
one or more memories storing instructions; and
one or more processors executing the instructions to:
obtain a read image obtained by optically reading the printed material;
specify a region pair formed of two regions, which are regions as an inspection target in the read image and which to be put in contact with each other in a case where the printed material is changed into a three-dimensional form; and
display the specified region pair on a display unit in an identifiable manner.

2. The information processing apparatus according to claim 1, wherein
the specification of the region pair is performed based on an image corresponding to the printed material.

3. The information processing apparatus according to claim 2, wherein
the specification of the region pair is performed by analyzing the image corresponding to the printed material.

4. The information processing apparatus according to claim 2, further comprising:
the one or more processors executing the instructions to:
display the image corresponding to the printed material on the display unit, wherein
the specification of the region pair is performed based on a user operation input for the image corresponding to the printed material displayed on the display unit.

5. The information processing apparatus according to claim 2, wherein
the image corresponding to the printed material is the read image or a 3D image expressing a shape in a case where the printed material is changed into the three-dimensional form.

6. The information processing apparatus according to claim 5, wherein
the display unit is a graphical user interface.

7. The information processing apparatus according to claim 6, further comprising:
the one or more processors executing the instructions to:
display the read image on the graphical user interface, wherein
the region pair is displayed to be superimposed on the read image in the graphical user interface.

8. The information processing apparatus according to claim 6, further comprising:
the one or more processors executing the instructions to:
display the 3D image on the graphical user interface, wherein
the region pair is displayed to be superimposed on the 3D image in the graphical user interface.

9. The information processing apparatus according to claim 6, wherein
in a case where a plurality of region pairs are displayed on the graphical user interface, a display manner of each of the region pairs is different.

10. The information processing apparatus according to claim 9, wherein
the display manner of each of the plurality of region pairs is different by using a static expression.

11. The information processing apparatus according to claim 10, wherein
the difference using the static expression is any one of a pattern difference, a color difference, and a difference in a character string to be added.

12. The information processing apparatus according to claim 9, wherein
the display manner of each of the plurality of region pairs is different by using a dynamic expression.

13. The information processing apparatus according to claim 12, wherein
the difference using the dynamic expression is, as to the plurality of region pairs, different blinking timings or sequential switching one by one.

14. The information processing apparatus according to claim 6, further comprising:
the one or more processors executing the instructions to:
display supplemental information indicating how the two regions forming the region pair are put in contact with each other in the three-dimensional form.

15. The information processing apparatus according to claim 1, further comprising:
the one or more processors executing the instructions to:
set a parameter for the inspection, wherein
the parameter for the regions of the region pair in the read image and the parameter for a region other than the regions of the region pair in the read image are set separately.

16. The information processing apparatus according to claim 15, wherein
the parameter is automatically set such that an inspection level for the regions of the region pair in the read image is stricter than an inspection level for the region other than the regions of the region pair in the read image.

17. The information processing apparatus according to claim 15, wherein
the parameter according to a feature amount of a pictorial pattern included in the printed material is automatically set.

18. The information processing apparatus according to claim 1, wherein
the printed material is a printed material to which an inspection mark corresponding to the region pair is added.

19. The information processing apparatus according to claim 18, further comprising:
the one or more processors executing the instructions to:
cause a printing apparatus to print the printed material to which the inspection mark is added.

20. The information processing apparatus according to claim 19, wherein
the inspection mark is printed on a margin of the printed material, which is a position close to each of the two regions forming the region pair.

21. The information processing apparatus according to claim 18, wherein
the inspection mark is a straight line extending in a direction in which positional misalignment sensitively reacts.

22. The information processing apparatus according to claim 18, wherein
the inspection mark is a color patch of at least one or more colors that are dominant in the two regions forming the region pair.

23. The information processing apparatus according to claim 1, further comprising:
the one or more processors executing the instructions to:
perform the inspection by comparing the read image and a reference image corresponding to the read image, wherein
in the inspection of the two regions forming the region pair,
an absolute difference with respect to the reference image of each of the two regions is calculated,
a relative difference of the absolute difference calculated with respect to the reference image of each of the two regions is calculated, and
whether the calculated relative difference exceeds an allowable value is determined.

24. A control method of an information processing apparatus configured to inspect a printed material, the control method comprising:
obtaining a read image obtained by optically reading the printed material;
specifying a region pair formed of two regions, which are regions as an inspection target in the read image and which are put in contact with each other in a case where the printed material is changed into a three-dimensional form; and
displaying the specified region pair on a display unit in an identifiable manner.

25. A non-transitory computer-readable storage medium storing a program for causing a computer to perform a control method of an information processing apparatus configured to inspect a printed material, the control method comprising:
obtaining a read image obtained by optically reading the printed material;
specifying a region pair formed of two regions, which are regions as an inspection target in the read image and which to be put in contact with each other in a case where the printed material is changed into a three-dimensional form; and
displaying the specified region pair on a display unit in an identifiable manner.
